(19) United States
(12) Patent Application Publication
(10) Pub. No.: US 2023/0360940 A1
(43) Pub. Date: Nov. 9, 2023

(54) WAFER FILM FRAME CARRIER

(71) Applicant: Applied Materials, Inc., Santa Clara, CA (US)

(72) Inventor: Jason A. Rye, Kalispell, MT (US)

(73) Assignee: Applied Materials, Inc., Santa Clara, CA (US)

(21) Appl. No.: 17/735,623

(22) Filed: May 3, 2022

(51) Int. Cl. H01L 21/673

(52) U.S. Cl. CPC H01L 21/67346; H01L 21/67326; H01L 21/67313

(57) ABSTRACT

Exemplary semiconductor substrate carrier frames may include a frame body defining a central aperture. The frames may include a plurality of fingers that are coupled with the frame body. Each of the plurality of fingers may extend into the central aperture. Each of the plurality of fingers may include a substrate receiving interface. At least one of the plurality of fingers may include an actuator that manipulates a respective one of the at least one of the plurality of fingers between a substrate holding position and an open position.

### TECHNICAL FIELD

The present technology relates to cleaning operations in semiconductor processing. More specifically, the present technology relates to systems and methods that perform in situ cleaning of wafers prior to packaging.

### BACKGROUND

Integrated circuits are made possible by processes which produce intricately patterned material layers on substrate surfaces. After the integrated circuits have been formed on a substrate, the substrate is typically diced into individual dies, and subsequently washed prior to being picked for packaging. Oftentimes, the diced substrate and a carrier substrate on which the dies may be placed for packaging may be washed right before the packaging operations. However, the carrier substrates and diced substrates are often different sizes, which necessitates the use of different chambers to complete the washing operations. The use of different chambers doubles the space needed for the chambers, as well as slows down the washing and packaging operations, as only one of each type of substrate may be washed at a time.

Thus, there is a need for improved systems and methods that can be used to produce high quality devices and structures while increasing throughput and/or reducing space demands. These and other needs are addressed by the present technology.

### SUMMARY

Exemplary semiconductor substrate carrier frames may include a frame body defining a central aperture. The frames may include a plurality of fingers that are coupled with the frame body. Each of the plurality of fingers may extend into the central aperture. Each of the plurality of fingers may include a substrate receiving interface. At least one of the plurality of fingers may include an actuator that manipulates a respective one of the at least one of the plurality of fingers between a substrate holding position and an open position.

In some embodiments, the plurality of fingers may include three fingers. Two of the fingers may be fixed in position. One of the fingers may include the actuator. Each of the plurality of fingers may include a dedicated actuator. Movement of the actuator between the substrate holding position and the open position may be controlled via a robotic arm. The actuator may include one or both of a pivoting actuator and a linear actuator. The frame may include four straight sides that are connected with one another via rounded corners interposed therebetween. A thickness of the frame at each of the straight sides may be between about 0.025 inches and 0.1 inches. When in the substrate holding position, a distance between the substrate receiving interfaces of the plurality of fingers may substantially match dimensions of a substrate being secured within the substrate carrier frame.

Some embodiments of the present technology may encompass semiconductor substrate carrier frames. The frames may include a frame body defining a central aperture. The frames may include at least two fixed fingers that are coupled with the frame body. Each of the fixed fingers may extend into the central aperture by a fixed distance. The frames may include at least one adjustable finger. Each adjustable finger may include an actuator that manipulates the respective adjustable finger between a substrate holding position and an open position. Each fixed finger and each adjustable finger may include a substrate receiving interface.

In some embodiments, each actuator may include one or more actuators selected from a group consisting of spring pin, a screw actuator, a pneumatic plungers system, a hydraulic plunger system, and a solenoid. An actuation distance of each actuator may be limited such that the substrate receiving interface of a respective adjustable finger does not extend beyond the substrate holding position when the actuator is fully extended. The frame body may include one or more grasping regions. Each fixed finger and each adjustable finger may be offset from the one or more grasping regions. When each of the at least one adjustable finger is in the substrate holding position, the substrate receiving interface of each adjustable finger and each fixed finger may be at a same radial distance from a center of the frame body. The at least two fixed fingers and the at least one adjustable finger may be arranged at equal intervals about the central aperture. Each substrate receiving interface may include a roller. Each substrate receiving interface may include a cylindrical body defining a groove. A width of the groove may correspond to a thickness of the substrate being secured by the substrate receiving interface. The groove may include walls that taper inward toward a center of the cylindrical body.

Some embodiments of the present technology may encompass methods of loading a semiconductor substrate into a substrate carrier frame. The methods may include positioning a substrate within a central aperture defined by a frame body of a substrate carrier frame. The methods may include manipulating at least one actuator coupled with one finger of a plurality of fingers that are coupled with the frame body to move the one finger from an open position to a substrate receiving position. The methods may include engaging an edge of the substrate with a plurality of substrate receiving interfaces. Each of the plurality of substrate receiving interfaces may be disposed on a respective one of the plurality of fingers.

In some embodiments, manipulating at least one actuator coupled with one finger of a plurality of fingers may include using a robotic arm to move the at least one actuator between the open position and the substrate receiving position. Positioning the substrate within the central aperture may include chucking the substrate to a chucking surface and positioning the frame body about the chucked substrate such that the chucked substrate is disposed within the central aperture.

Such technology may provide numerous benefits over conventional technology. For example, the present technology may provide substrate carrier frames that enable a smaller substrate to be adapted for use with a chamber designed to clean and/or process a larger substrate and/or a substrate mounted on a film frame. Accordingly, the substrate carrier frames of the present technology may enable a single chamber design to be utilized with substrates of various sizes, without the need to modify or adapt the chamber or components thereof. These and other embodiments, along with many of their advantages and features, are described in more detail in conjunction with the below description and attached figures.

### BRIEF DESCRIPTION OF THE DRAWINGS

A further understanding of the nature and advantages of the disclosed embodiments may be realized by reference to the remaining portions of the specification and the drawings.

FIG. 1 shows a schematic perspective view of an exemplary wet clean tool according to some embodiments of the present technology.

FIG. 2A shows a schematic perspective view of an exemplary carrier frame according to some embodiments of the present technology.

FIG. 2B shows a schematic perspective view of the carrier frame of FIG. 2A in a substrate holding position.

FIG. 2C shows an enlarged schematic perspective view of the carrier frame of FIG. 2A.

FIG. 2D shows an enlarged schematic perspective view of the carrier frame of FIG. 2A in a substrate holding position.

FIG. 3 shows a schematic top plan view of an exemplary carrier frame according to some embodiments of the present technology.

FIG. 4 shows a schematic front elevation view of a buffer station according to some embodiments of the present technology.

FIG. 5 shows operations of an exemplary method of loading a semiconductor substrate into a substrate carrier frame according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the figures, similar components and/or features may have the same numerical reference label. Further, various components of the same type may be distinguished by following the reference label by a letter that distinguishes among the similar components and/or features. If only the first numerical reference label is used in the specification, the description is applicable to any one of the similar components and/or features having the same first numerical reference label irrespective of the letter suffix.

### DETAILED DESCRIPTION

Various operations in semiconductor manufacturing and processing are performed to produce vast arrays of features across a substrate. As layers of semiconductors are formed, vias, trenches, and other pathways are produced within the structure. These features may then be filled with a conductive or metal material that allows electricity to conduct through the device from layer to layer. Once formed, these features may form numerous integrated circuits on the semiconductor substrate. These integrated circuits are then harvested by dicing the substrate into individual integrated circuits, which may then be positioned atop a carrier wafer or other substrate for assembly and packaging into one or more electrical components.

Oftentimes, after dicing of the substrate, the substrate may be subject to one or more cleaning operations to remove any residue, debris, and/or other defects from the dicing and/or other processing operations. Similarly, the carrier wafer may be cleaned prior to any individual dies being placed upon the carrier wafer. However, the carrier wafer and the diced substrate may be different sizes and/or shapes. For example, prior to being diced, the diced substrate may be placed upon an adhesive film frame, which may help hold the individual dies in place after they have been separated by the dicing process. The diced substrate may remain on the film frame during the cleaning operations. In some embodiments, the carrier wafer may be larger or smaller than the diced substrate. Due to the different size and/or shape of the diced substrate and carrier wafer, it is often necessary to utilize separate wet clean chambers to clean the diced substrate and carrier wafer, despite similar or identical cleaning chemistries being used to clean each substrate. The use of separate chambers results in greater space needs to accommodate the different chamber designs, and also limits throughput of the system. Due to the complexity in handling the different sizes and/or shapes of substrates, it is typically not feasible to design a single chamber that is capable of handling the different geometry of the diced wafers and carrier wafers. Additionally, the numbers of diced substrates and carrier wafers needed for packaging is often different (e.g., more diced substrates may be needed than carrier wafers, such as when multiple dies are stacked on a carrier wafer), which may result in throughput issues, as it may take longer to clean or otherwise process all substrates within a batch of one substrate type than the other.

The present technology overcomes these issues by providing substrate carrier frames that enable different sized substrates to be cleaned or otherwise processed in a single chamber. For example, in some embodiments, the carrier frames may enable two different sizes of substrates (e.g., a 200 mm and a 300 mm substrate) to be processed in a given chamber. In some embodiments, the carrier frames may enable a carrier wafer to be processed in a same chamber as a diced substrate, which may be secured on an adhesive film frame. For example, the carrier frame may be sized and shaped to match the dimensions of the film frame, which may enable a carrier wafer secured by the carrier frame to be processed using the same equipment as the diced wafer in the film frame. For example, the same robotic tooling and chamber supports may be used to support the carrier frame and the film frame, without needing to make any adaptations to the chamber or robot tool equipment. Such a carrier frame provides flexibility in the use of chambers. For example, a single chamber may be used to clean and/or otherwise process multiple types of substrates, which may save space within the fabrication facility. In embodiments that include multiple chambers, the chambers may be run in parallel with each chamber processing either type of substrate, which may help increase throughput as both chambers may be active, even after the full batch of one substrate type has been fully processed.

Although the remaining disclosure will routinely identify specific carrier frames and wet cleaning operations utilizing the disclosed technology, it will be readily understood that the systems and methods are equally applicable to a variety of other semiconductor processing operations and systems. In particular, the carrier frames described herein may be utilized in any chamber or other processing equipment, especially those in which multiple substrate and/or frame sizes are handled. Accordingly, the technology should not be considered to be so limited as for use with the described cleaning systems or processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems, along with any number of modifications, some of which will be noted below.

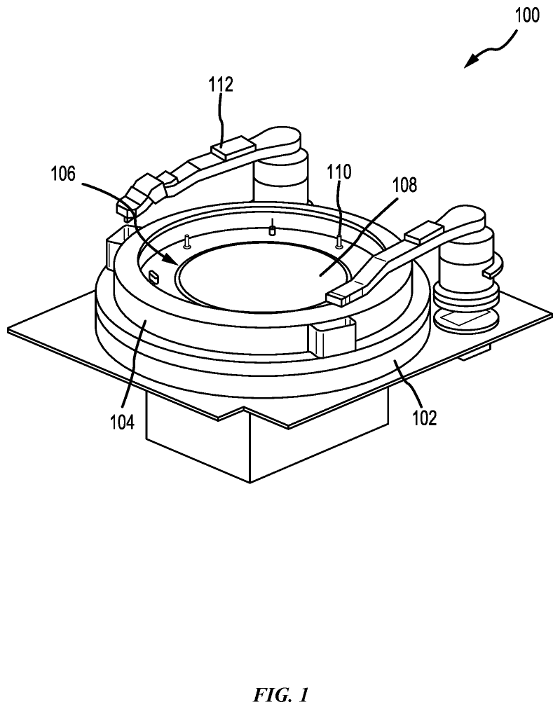

FIG. 1 illustrates a schematic isometric view of a wet clean tool 100, which may be specifically configured to implement aspects or operations according to some embodiments of the present technology. The wet clean tool 100 may be configured to perform one or more cleaning processes on individual substrates, such as any number of semiconductor substrates, for forming semiconductor devices. The wet clean tool 100 may include components that may be maintained at atmospheric pressure, which may be any pressure within a processing facility, such as including positive or negative pressure environments. The system may also include components that are maintained under vacuum conditions, and which may be separated from the atmospheric components by a load lock system, for example.

Wet clean tool 100 may include a chamber body 102 that may include one or more sidewalls 104 that define a cleaning region 106 within the chamber body 102. As illustrated, the sidewalls 104 may include an annular sidewall that defines a generally cylindrical cleaning region 106. The cleaning region 106 may provide space for one or more substrates to be supported during cleaning operations. As illustrated, the wet clean tool 100 provides space for a single substrate mounted on a frame, such as a film frame or a carrier frame (as will be discussed in greater detail below), to be supported within the cleaning region 106. Wet clean tool 100 may include one or more substrate supports 108, which may include a number of frame grasping members 110 that protrude outward from a top surface of the substrate support 108. The frame grasping members 110 and substrate support 108 may be recessed relative to a top surface of the sidewalls 104 such that an open volume is provided above the frame grasping members 110. Each frame grasping member 110 may be designed to grasp or otherwise secure edges of a frame (which may carry a substrate) atop the substrate support 108. Three or more frame grasping members 110 may be provided such that a frame held by the frame grasping members 110 may be securely supported in a horizontal fashion relative to the substrate support 108, without the frame tilting. In some embodiments, four frame grasping members 110 may be provided at 90 degree intervals such that each frame grasping member 110 may grasp a respective one of four straight sides of a frame, although other numbers and/or arrangements of frame grasping members 110 may be utilized in various embodiments.

The substrate support 108 and frame grasping members 110 may be coupled with a rotating actuator (not shown), which may be used to selectively spin the substrate support 108 and frame grasping members 110 (and a frame and substrate secured by the frame grasping members 110) during cleaning operations. Each wet clean tool 100 may be fluidly coupled with one or more chemistry delivery systems (not shown), which may include pumps, tubing, and other materials for delivering one or more process chemistries to the wet clean tool 100. For example, the chemistries may be delivered to the cleaning region 106 using one or more delivery arms 112, which may each be rotated between a substrate loading position and a delivery position. For example, as illustrated, each delivery arm 112 is in a substrate loading position in which the respective delivery arm 112 is positioned radially outward of the cleaning region 106, which may enable space for a substrate and frame to be inserted into or removed from the cleaning region 106. During clean operations, one or both of the delivery arms 112 may be rotated inward such that the respective delivery arm 112 is positioned over the cleaning region 106 and a substrate disposed therein. One or more process chemistries may be delivered to the substrate within the cleaning region 106 via a dispensing port of the delivery arm 112. For example, the chemistries may be delivered to a top surface of the substrate. Before, during, and/or after delivery of the one or more chemistries, the substrate support 108 and frame grasping members 110 may be rotated to spin the substrate and frame. The spinning motion may help distribute the one or more chemistries across the entire surface of the substrate and/or may help remove excess chemicals from the surface of the substrate after the cleaning is complete.

Any number of wet clean processes may be performed according to aspects of the present technology, and in some embodiments the wet cleaning may include multiple cleaning processes and chemistries. For example, in some embodiments a set of chemistries for a wet cleaning operation may include a first chemistry including hydrofluoric acid, a second chemistry including ammonium hydroxide, and/or a third chemistry including hydrochloric acid. It is to be understood that the chemistries may come from one or more fluid sources and be delivered to one or more wet clean tools 100. Additionally, it is to be understood that the fluid delivery systems may be included with the wet clean tool 100. Once cleaning operations have been performed, the delivery arms 112 may be returned to the substrate loading position to enable the substrate and frame to be removed from the wet clean tool 100. The insertion and removal of the substrate and frame may be performed via a transfer robot in some embodiments. In some embodiments, single-substrate wet clean tools 100 may be provided side-by-side and/or may be stacked in some embodiments, which may allow individual processes to be performed in each tool, or may allow multiple substrates to be processed simultaneously, for example.

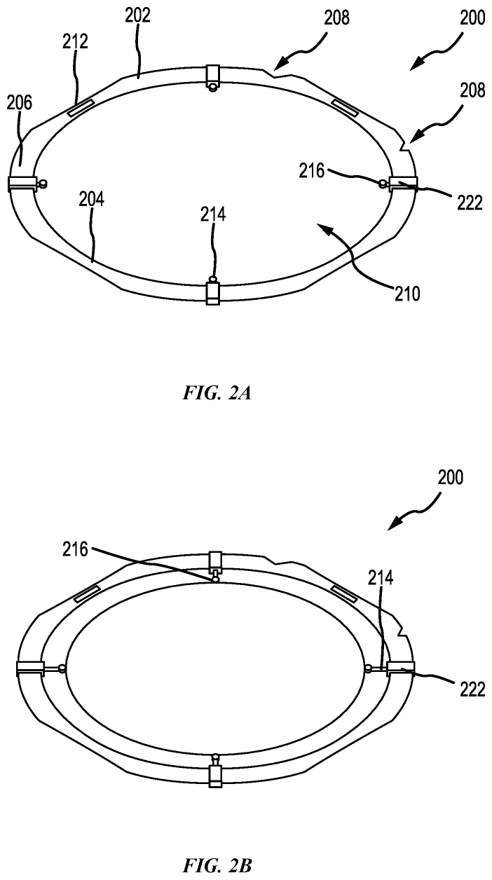

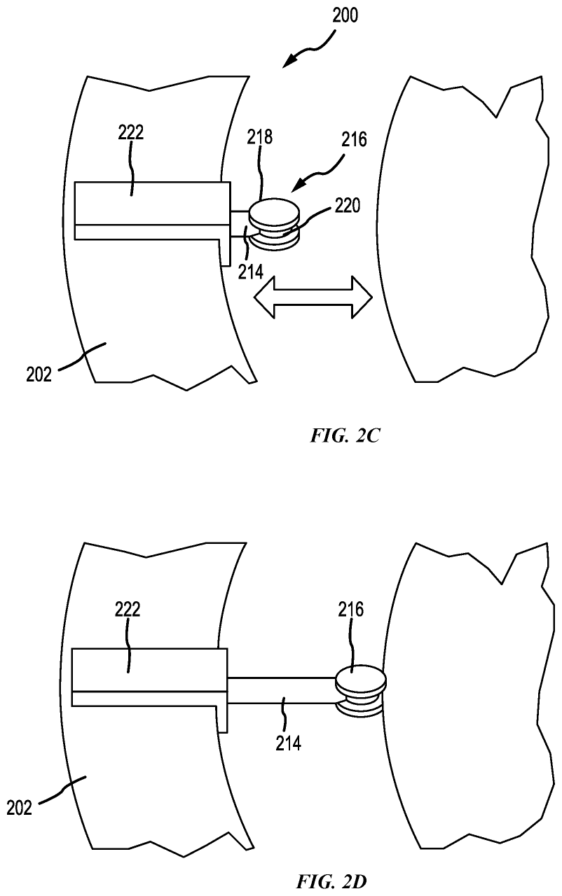

FIG. 2A illustrates a schematic isometric view of an exemplary substrate carrier frame 200 according to some embodiments of the present technology. The carrier frame 200 may show a partial view of the components being discussed and that may be utilized with one or more processing chambers, such as wet clean tool 100. The carrier frame 200 may be used to hold substrates, such as (but not limited to) carrier substrates prior to being inserted within a particular processing chamber. For example, the carrier frame 200 may serve as an adaptor that enables a single transfer robot, chamber, and/or other processing component to accommodate different sizes of substrates and/or frames without modifying the tooling of the transfer robot, chamber, and/or other processing component.

The carrier frame 200 may include a frame body 202, which may be generally annular in shape. For example, as illustrated the carrier frame 200 may include four straight sides 204 that have generally linear outer edges and that are arranged in opposing pairs, with the pairs being generally orthogonal to one another so as to form a generally rectangular shape. In some embodiments, the frame body 202 may include rounded corners 206 that are interposed between adjacent straight sides 204. In such a manner, the frame body 202 may form a generally rectangular (e.g., square) shape, with rounded corners. In a particular embodiment, the frame body 202 may be formed from an annular shape that has had four semicircular sections removed at equal intervals (e.g., 90 degrees) to form the generally rectangular shape. In such embodiments, a width of the frame body 202 may be thicker at the rounded corners 206 than along all or a portion of each straight side 204 where material has been removed. In some embodiments, In some embodiments, the frame body 202 may define a number of positioning notches 208, which may be configured to receive guide pins that may be used to align the carrier frame 200 within processing tools and/or chambers. The frame body 202 may define a central aperture 210 that may be generally circular in shape in some embodiments. A diameter of the central aperture 210 may be selected to be larger than a diameter of a substrate that the carrier frame 200 is designed to secure. The frame body 202 may include a number of grasping regions 212 that provide locations for transfer robots, chamber components, and/or other processing equipment to grasp and/or otherwise support the carrier frame 200. The grasping regions 212 may be provided on two or more of the straight sides 204, such as straight sides 204 on either side of the positioning notches 208.

The frame body 202 may be sized and shaped to generally match the size and shape of a film frame used to secure a diced substrate as described above. For example, the lateral dimensions of the frame body 202 may be selected to match a length and/or width of an existing film frame in some embodiments. The central aperture 210 may be sized to be larger than a substrate that is to be received within the central aperture 210. For example, a diameter of the central aperture 210 may be at least or about 1% larger than a diameter of the substrate, at least or about 2% larger, at least or about 3% larger, at least or about 4% larger, at least or about 5% larger, at least or about 10% larger, at least or about 15% larger, at least or about 20% larger, or more. In other terms, a diameter of the central aperture 210 may be at least or about 5 mm larger than a diameter of the substrate, at least or about 10 mm larger, at least or about 20 mm larger, at least or about 30 mm larger, at least or about 40 mm larger, at least or about 50 mm larger, at least or about 60 mm larger, or more.

A thickness of the frame body 202 may be substantially uniform. In a particular embodiment, a thickness of the frame body 202 may be between or about 0.025 inches and 0.1 inches, between or about 0.03 inches and 0.09 inches, between or about 0.035 inches and 0.08 inches, between or about 0.04 inches and 0.07 inches, between or about 0.045 inches and 0.065 inches, or between or about 0.05 inches and 0.06 inches, which may be measured, for example, along one of the straight sides 204 and/or grasping regions 212. In some embodiments, a thickness of the frame body 202 may be substantially the same or smaller than a thickness of the substrate. The frame body 202 may be sized to accommodate a particular size of substrate, and a number of frame bodies 202 may be provided that are sized based on a corresponding substrate size (e.g., 100 mm, 150 mm, 200 mm, 300 mm, 400 mm, etc.).

The carrier frame 200 may include a number of fingers 214 that are coupled with the frame body 202, with each finger 214 extending radially inward into the central aperture 210. As best illustrated in FIG. 2C, each finger 214 may include a substrate receiving interface 216, which may be secured at a distal (e.g., innermost) end of the respective finger 214. Each substrate receiving interface 216 may be sized and shaped to receive and secure an edge of the substrate. For example, each substrate receiving interface 216 may include a cylindrical body 218 that defines a horizontal groove 220. The width of the groove 220 may correspond to a thickness of a substrate such that an edge of the substrate may be received within the groove 220. In some embodiments, to facilitate insertion and alignment of a substrate within the groove 220, walls of the groove 220 may be tapered inward in a direction of a center of the cylindrical body 218. This may provide a wider opening through which the edge of the substrate may be inserted, with the tapered walls guiding the substrate toward a center of the groove 220, which may itself be aligned with a center of the frame body 202 in some embodiments. Oftentimes, the substrate receiving interfaces 216 may be static components, however it some embodiments the substrate receiving interfaces 216 may include rollers and/or other dynamic components that may enable the substrate to spin or otherwise rotate within the carrier frame 200. This may be particularly beneficial in some cleaning operations, as the edges of the substrate covered by the substrate receiving interfaces 216 may be exposable during cleaning operations. For example, a rate of spinning of the substrate support and/or frame grasping members may be reduced (or stopped), which may enable the substrate to spin relative to the carrier frame 200 via the rolling elements of the substrate receiving interfaces 216, which may enable the previously obscured regions to become uncovered such that cleaning solutions may reach such regions of the substrate. It will be appreciated that other substrate receiving interface designs are possible in various embodiments.

Each substrate receiving interface 216 may be formed from a material that is nonreactive or otherwise chemically resistant to the cleaning and/or other process chemistries. The material may also be sufficiently soft so as to not scratch or otherwise damage the substrate. In a particular embodiment, each substrate receiving interface 216 may be formed from a polymeric material, such as polytetrafluoroethylene (PTFE) and/or polyetheretherketone (PEEK), although other suitable polymers may be used in various embodiments.

The carrier frame 200 may include at least or about 3 fingers, at least or about 4 fingers, at least or about 5 fingers, at least or about 6 fingers, or more. The fingers 214 may be spaced apart about the central aperture 210 at regular and/or irregular angular intervals. As illustrated, the carrier frame 200 includes four fingers 214 that are spaced apart at 90 degree intervals. The fingers 214 may be positioned at any location about the frame body 202 (e.g., on straight sides 204 and/or rounded corners 206). In some embodiments, the fingers 214 may be positioned on the wider rounded corners 206, which may provide more frame body material on which to mount the fingers 214 and may also ensure that the fingers 214 are angularly offset from the grasping regions 212 such that the presence of the fingers 214 does not interfere with the ability of grasping and/or support components of transfer devices and/or chambers to grasp or otherwise support the grasping regions 212 of the frame body 202.

In some embodiments, some of the fingers 214 may be fixed in place such that the substrate receiving interface 216 of the fixed finger 214 remains at a fixed distance relative to the center of the central aperture 210 at all times. One or more (and potentially all) of the fingers 214 may include an actuator 222 that enables the finger 214 to be adjustable. For example, each adjustable finger 214 may include an actuator 222 that manipulates the respective adjustable finger between a substrate holding position and an open position. In the open position (as best illustrated in FIGS. 2A and 2C), the substrate receiving interface 216 of the finger 214 may be brought closer to the frame body 202 and further from a center of the central aperture 210. In the substrate holding position, the substrate receiving interface 216 may be positioned further from the frame body 202 and closer to the center of the central aperture 210 (as best illustrated in FIGS. 2B and 2D). In other words, in the substrate holding position, the substrate receiving interface 216 of each finger 214 may be positioned at a radial distance from a center of the central aperture 210 that substantially matches (e.g., within or about 2%, within or about 1%, within or about 0.5%, or less) a radius of the substrate being secured, such that when in the substrate holding position the substrate receiving interface 216 may engage an edge of the substrate. In other words, when in the substrate holding position, a distance between the substrate receiving interfaces 216 of each of the fingers (fixed and adjustable) substantially matches dimensions of a substrate being secured within the substrate carrier frame such that the substrate may be securely constrained by the carrier frame 200 as best illustrated in FIG. 2B. In some embodiments, each actuator 222 may be designed such that any actuation distance is limited such that the substrate receiving interface 216 of a respective adjustable finger 214 does not extend beyond the substrate holding position when the actuator 222 is fully extended. This may ensure that the actuators 222 do not apply excessive compressive force between the various fingers 214 that could damage the substrate. When each adjustable finger 214 is in the substrate holding position, the substrate receiving interface 216 of each adjustable finger 214 and each fixed finger 214 (if present) may be at a same radial distance from a center of the frame body 202 and/or central aperture 210 such that the substrate may be centered with respect to the frame body 202 and/or central aperture 210.

In some embodiments, only a single finger 214 or a small subset of fingers 214 may include an actuator 222, while the rest of the fingers 214 are fixed. In other embodiments, all of the fingers 214 include their own dedicated actuator 222 and may be moveable between the open position and the substrate holding position. The actuators 222 may take various forms. For example, in some embodiments, the actuators 222 may include pivoting actuators and/or linear actuators. When in the open position, pivoting actuators may be pivoted such that the finger 214 points away from a center of the central aperture 210 and may be closer to the walls of the frame body 202. In the substrate holding position, pivoting actuators may be pivoted such that the finger 214 points more to the center (and possibly directly through the center) of the central aperture 210, with the substrate receiving interfaces 216 disposed at a most radially inward position relative to the center of the central aperture 210. When in the open position, linear actuators retract the finger 214 away from a center of the central aperture 210 such that the substrate receiving interface 216 is drawn closer to the walls of the frame body 202 (as best illustrated in FIGS. 2A and 2C). In the substrate holding position, linear actuators may extend the finger 214 inward toward the center of the central aperture 210, with the substrate receiving interfaces 216 disposed at a most radially inward position relative to the center of the central aperture 210 (as best illustrated in FIGS. 2B and 2D). Suitable linear actuators may include a spring pin, a screw actuator, a pneumatic plungers system, a hydraulic plunger system, a solenoid, and/or other linear actuators.

Oftentimes, the actuator 222 may be selected such that the actuator 222 may remain in the substrate holding position without any outside forces (e.g., hydraulics, electric signals, pneumatic pressure, etc.). This may enable the carrier frame 200 to securely hold a substrate when the substrate is positioned within various tools and chambers of a processing system (e.g., when in a neutral state without any external forces being applied to the actuator 222). For example, the actuator 222 may be biased toward the substrate holding position and/or otherwise have the substrate holding position as a default/neutral position. In embodiments in which an external force (e.g., hydraulics, electric signals, pneumatic pressure, etc.) is needed to move the actuator 222, the external force may be used to move the actuator 222 from the substrate holding position to the open position, while removal of the external force may enable the actuator 222 to return to the substrate holding position. For example, for a solenoid actuator, application of a current may cause the actuator 222 to retract the finger 214 and substrate receiving interface 216. Similarly, for a spring loaded pin or other spring force actuator, an external force may be used to retract the substrate receiving interface 216, while the spring force (e.g., from a compression spring) may bias the substrate receiving interface 216 toward the substrate holding position when the external force is removed. In some embodiments, the actuator 222 may include a mechanical engagement mechanism. For example, the actuator 222 may have a drive recess (e.g., a screw head), cam, or other feature that may be rotated to move the actuator 222 between the substrate holding position and the open position. As just one example, rotating the drive recess and/or cam may turn a leadscrew and/or other screw actuator to retract and extend the finger 214. In some embodiments, movement of the actuator 222 between the substrate holding position and the open position may be controlled via a robotic arm, such as from a transfer robot and/or other robotic device. For example, the robotic arm may include tooling that may be inserted, may grasp, and/or may otherwise engage a corresponding feature of the actuator 222 to manipulate the actuator 222 between the substrate holding position and the open position. In embodiments where hydraulics, electric signals, pneumatic pressure, etc. are needed to operate the actuator 222, the robotic arm may include a tool that may supply the necessary external force (e.g., a hydraulic pressure source, a pneumatic pressure source, an electric current source, etc.) to the actuator 222.

The presence of the fingers 214 and/or actuators 222 may increase the thickness of the carrier frame 200. For example, the thickness of the fingers 214 and/or actuators 222 may be between or about 0.1 inches and 0.5 inches, between or about 0.15 inches and 0.45 inches, between or about 0.2 inches and 0.4 inches, between or about 0.25 inches and 0.35 inches, or about 0.35 inches in some embodiments. Such thicknesses may provide sufficient material to rigidly hold the substrate within the central aperture 210 while also ensuring that the carrier frame 200 does not cause a significant disruption (e.g., flowpath disruption during cleaning and/or other processing operations).

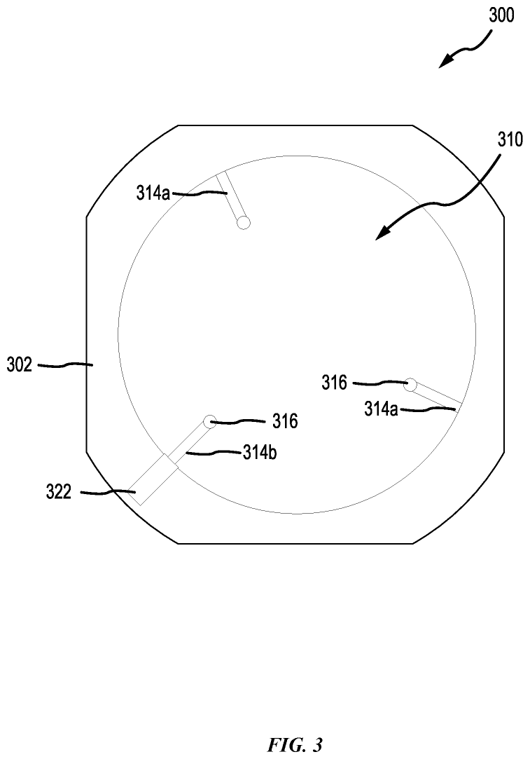

FIG. 3 illustrates a schematic isometric view of an exemplary substrate carrier frame 300 according to some embodiments of the present technology. The carrier frame 300 may show a partial view of the components being discussed and that may be utilized with one or more processing chambers, such as wet clean tool 100. The carrier frame 300 may be similar to carrier frame 200 and may include any of the features described in relation to carrier frame 200. Carrier frame 300 may be used to hold substrates, such as (but not limited to) carrier substrates prior to being inserted within a particular processing chamber. For example, the carrier frame 300 may serve as an adaptor that enables a single transfer robot, chamber, and/or other processing component to accommodate different sizes of substrates without modifying the tooling of the transfer robot, chamber, and/or other processing component.

As illustrated, carrier frame 300 includes a frame body 302 that defines a central aperture 310. Carrier frame 300 includes two fixed fingers 314a that extends into the central aperture by a fixed distance and one adjustable finger 314b that may extend and retract relative to the central aperture 310. Each finger 314 may include a substrate receiving interface 316 that may be sized and shaped to receive and secure an edge of a substrate. The adjustable finger 314b may include an actuator 322 that manipulates the respective adjustable finger between a substrate holding position and an open position, wherein each fixed finger and each adjustable finger comprises a substrate receiving interface. As illustrated, the fixed fingers 314a and the adjustable finger 314b are arranged at equal intervals (e.g., every 120 degrees) about the central aperture 310. In operation, a substrate may be positioned in the central aperture 310. The actuator 322 may extend the adjustable finger 314b to the substrate receiving position, which may cause the substrate receiving interface 316 of the adjustable finger 314b to press the substrate into engagement with the substrate receiving interfaces 316 of the fixed fingers 314a. In some embodiments, the actuation of the adjustable finger 314b may enable the substrate to be positioned within the central aperture 310 offset from a center of the central aperture 310, with the actuation of the adjustable finger 314b (in conjunction with the fixed position of the fixed fingers 314a) serving to center the substrate within the carrier frame 300.

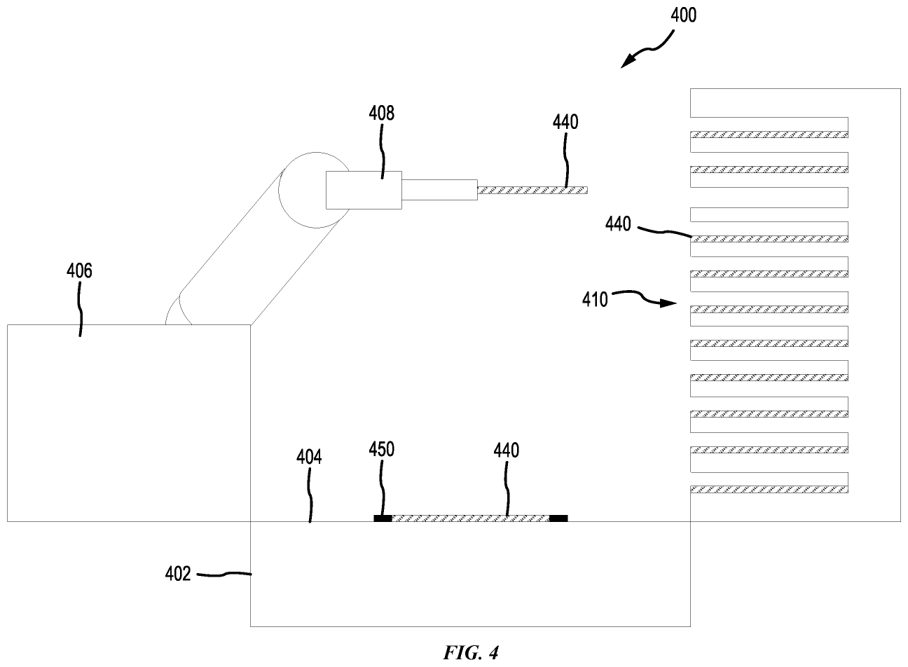

FIG. 4 illustrates a schematic front elevation view of an exemplary buffer station 400 according to some embodiments of the present technology. The buffer station 400 may show a partial view of the components being discussed and that may be utilized with one or more processing chambers, such as wet clean tool 100. The buffer station may be used to load substrates 440 into carrier frames 450, such as carrier frame 200 and carrier frame 300. Buffer station 400 may include a chuck mechanism 402 that includes a substrate support surface 404. The chuck mechanism 402 may operate as a vacuum chuck, an electrostatic chuck, and/or other type of chuck in various embodiments. The buffer station 400 may include one or more robotic transfer mechanisms 406, which may each include one or more arms 408 that are designed to engage a substrate 440 and/or a carrier frame 450. The buffer station 400 may include one or more slots 410 that are sized and shaped to hold substrates 440, carrier frames 450, and/or carrier frames that are carrying a substrate. The slots 410 may be arranged (such as vertically stacked) to enable a number of substrates 440 and/or frames 450 to be prepared for cleaning and/or other processing operations. In some embodiments, the buffer station 400 may be positioned proximate one or more processing tools and/or chambers, such as wet clean tool 100 described herein.

In operation, the transfer mechanism 406 may position a substrate atop the substrate support surface 404. In some embodiments, the substrate may be retrieved from one of the slots 410. A chucking force may be applied to the substrate 440 to secure the substrate 440 in place. A carrier frame 450 may be positioned about the substrate 440 using an arm 408 of the transfer mechanism 406 before or after the substrate 440 has been positioned atop the substrate support surface 404. In some embodiments, the carrier frame 450 may be retrieved from one of the slots 410. An arm 408 of the transfer mechanism 406 may manipulate one or more actuators of the carrier frame 450 to a substrate holding position in which edges of the substrate 440 are secured by substrate receiving interfaces provided on fingers of the carrier frame 450. During and/or after the securing of the substrate 440 within the carrier frame 450, the chucking force may be removed, and the transfer mechanism 406 may move the carrier frame and substrate assembly to a slot 410 and/or into an adjacent chamber or other processing tool.

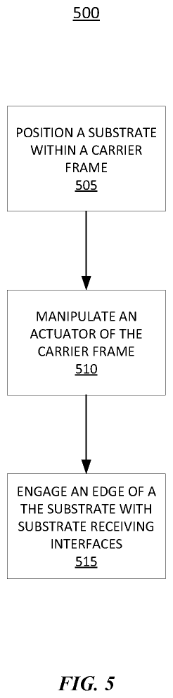

FIG. 5 shows exemplary operations in a method 500 for loading a semiconductor substrate into a substrate carrier frame according to some embodiments of the present technology. Method 500 may be performed using carrier frame (such as carrier frame 200 and 300) and/or a buffer station (such as buffer station 400) described herein. Method 500 may include operations prior to the frame loading in some embodiments. Method 500 may include a number of operations that may be performed automatically within a system to limit manual interaction, and to provide increased efficiency and precision over manual operations. Method 500 may be performed as part of or in conjunction with a conventional cleaning process in some embodiments.

Method 500 may include positioning a substrate within a central aperture defined by a frame body of a substrate carrier frame at operation 505. Positioning the substrate within the central aperture may include using a robotic arm to move the substrate from a load lock, buffer station slot, and/or other location to a substrate support surface of a chuck mechanism. The substrate may be chucked to a chucking surface, and the frame body may be positioned about the chucked substrate on the substrate support surface such that the chucked substrate is disposed within the central aperture. In some embodiments, the carrier frame may be placed upon the chuck mechanism before the substrate, while in other embodiments, the carrier frame may be placed upon the chuck mechanism after the substrate. A robotic arm (which may be the same or different than the arm used to move the substrate) may be used to move the carrier frame from a buffer station slot to the substrate support surface. Once the substrate is positioned within the central opening, the method 500 may include manipulating one or more actuators (which may be similar to actuators 222 and 318) to move a respective adjustable finger of the carrier frame from an open position to a substrate receiving position at operation 510. For example, a cam, drive recess, and/or other (mechanical, hydraulic, pneumatic, electrical, etc.) device may be rotated, pressed, and/or otherwise manipulated to operate the actuator, which may enable substrate receiving interfaces of each finger (which may include only adjustable fingers or a combination of fixed and adjustable fingers) to engage an edge of the substrate to secure the substrate within the carrier frame at operation 515. In some embodiments, the manipulation of the actuator may be performed using an arm of the robotic device.

Once the substrate has been loaded within the carrier frame, the chucking force may be removed, and the carrier frame (and substrate) may be transferred to a buffer station slot to await transfer to a processing chamber or tool. In other embodiments, the loaded carrier frame may be transferred directly to a processing chamber or tool. The transfer may be performed by a robotic arm. In a particular embodiment, the loaded carrier frame may be transferred to a wet clean tool, such as wet clean tool 100. In such embodiments, the loaded carrier frame may be secured atop a substrate support (such as substrate support 108), such as using a number of frame grasping members (such as frame grasping members 110) that are provided within a cleaning region of the wet clean tool. The substrate support may be spun, and one or more cleaning chemistries may be applied to the substrate.

In the preceding description, for the purposes of explanation, numerous details have been set forth in order to provide an understanding of various embodiments of the present technology. It will be apparent to one skilled in the art, however, that certain embodiments may be practiced without some of these details, or with additional details. For example, other processing operations that may benefit from the carrier frames described may also be used with the present technology.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. Where multiple values are provided in a list, any range encompassing or based on any of those values is similarly specifically disclosed.

As used herein and in the appended claims, the singular forms “a”, “an”, and “the” include plural references unless the context clearly dictates otherwise. Thus, for example, reference to “a material” includes a plurality of such materials, and reference to “the channel” includes reference to one or more channels and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor substrate carrier frame, comprising:
a frame body defining a central aperture;
a plurality of fingers that are coupled with the frame body, each of the plurality of fingers extending into the central aperture, wherein:
each of the plurality of fingers comprises a substrate receiving interface; and
at least one of the plurality of fingers comprises an actuator that manipulates a respective one of the at least one of the plurality of fingers between a substrate holding position and an open position.

2. The semiconductor substrate carrier frame of claim 1, wherein:
the plurality of fingers comprise three fingers;
two of the fingers are fixed in position; and
one of the fingers comprises the actuator.

3. The semiconductor substrate carrier frame of claim 1, wherein:
each of the plurality of fingers comprises a dedicated actuator.

4. The semiconductor substrate carrier frame of claim 1, wherein:
movement of the actuator between the substrate holding position and the open position is controlled via a robotic arm.

5. The semiconductor substrate carrier frame of claim 1, wherein:
the actuator comprises one or both of a pivoting actuator and a linear actuator.

6. The semiconductor substrate carrier frame of claim 1, wherein:
the frame comprises four straight sides that are connected with one another via rounded corners interposed therebetween.

7. The semiconductor substrate carrier frame of claim 6, wherein:
a thickness of the frame at each of the straight sides is between about 0.025 inches and 0.1 inches.

8. The semiconductor substrate carrier frame of claim 1, wherein:
when in the substrate holding position, a distance between the substrate receiving interfaces of the plurality of fingers substantially matches dimensions of a substrate being secured within the substrate carrier frame.

9. A semiconductor substrate carrier frame, comprising:
a frame body defining a central aperture;
at least two fixed fingers that are coupled with the frame body, each of the fixed fingers extending into the central aperture by a fixed distance; and
at least one adjustable finger, each adjustable finger comprising an actuator that manipulates the respective adjustable finger between a substrate holding position and an open position, wherein each fixed finger and each adjustable finger comprises a substrate receiving interface.

10. The semiconductor substrate carrier frame of claim 9, wherein:
each actuator comprises one or more actuators selected from a group consisting of spring pin, a screw actuator, a pneumatic plungers system, a hydraulic plunger system, and a solenoid.

11. The semiconductor substrate carrier frame of claim 9, wherein:
an actuation distance of each actuator is limited such that the substrate receiving interface of a respective adjustable finger does not extend beyond the substrate holding position when the actuator is fully extended.

12. The semiconductor substrate carrier frame of claim 9, wherein:
the frame body comprises one or more grasping regions; and
each fixed finger and each adjustable finger is offset from the one or more grasping regions.

13. The semiconductor substrate carrier frame of claim 9, wherein:
when each of the at least one adjustable finger is in the substrate holding position, the substrate receiving interface of each adjustable finger and each fixed finger is at a same radial distance from a center of the frame body.

14. The semiconductor substrate carrier frame of claim 9, wherein:
the at least two fixed fingers and the at least one adjustable finger are arranged at equal intervals about the central aperture.

15. The semiconductor substrate carrier frame of claim 9, wherein:
each substrate receiving interface comprises a roller.

16. The semiconductor substrate carrier frame of claim 9, wherein:
each substrate receiving interface comprises a cylindrical body defining a groove; and
a width of the groove corresponds to a thickness of the substrate being secured by the substrate receiving interface.

17. The semiconductor substrate carrier frame of claim 16, wherein:
the groove comprises walls that taper inward toward a center of the cylindrical body.

18. A method of loading a semiconductor substrate into a substrate carrier frame, comprising:
positioning a substrate within a central aperture defined by a frame body of a substrate carrier frame;
manipulating at least one actuator coupled with one finger of a plurality of fingers that are coupled with the frame body to move the one finger from an open position to a substrate receiving position; and
engaging an edge of the substrate with a plurality of substrate receiving interfaces, wherein each of the plurality of substrate receiving interfaces is disposed on a respective one of the plurality of fingers.

19. The method of loading a semiconductor substrate into a substrate carrier frame of claim 18, wherein:
manipulating at least one actuator coupled with one finger of a plurality of fingers comprises using a robotic arm to move the at least one actuator between the open position and the substrate receiving position.

20. The method of loading a semiconductor substrate into a substrate carrier frame of claim 18, wherein:
positioning the substrate within the central aperture comprises:
chucking the substrate to a chucking surface; and
positioning the frame body about the chucked substrate such that the chucked substrate is disposed within the central aperture.
